(19) United States
(12) Patent Application Publication
(10) Pub. No.: US 2013/0256718 A1
(43) Pub. Date: Oct. 3, 2013

(54) LIGHT EMITTING DEVICE AND MANUFACTURING METHOD THEREOF

(71) Applicants: WINSKY TECHNOLOGY LIMITED, Hong Kong (HK); KUN-HSIN TECHNOLOGY INC., Taipei City (TW)

(72) Inventor: Kun Chuan LIN, TAIPEI CITY (TW)

(73) Assignees: KUN-HSIN TECHNOLOGY INC., Taipei City (TW); WINSKY TECHNOLOGY LIMITED, Hong Kong (HK)

(21) Appl. No.: 13/853,471

(22) Filed: Mar. 29, 2013

(30) Foreign Application Priority Data
Mar. 30, 2012 (TW) 101111571

(51) Int. Cl. H01L 33/44; H01L 33/00

(52) U.S. Cl. CPC H01L 33/44; H01L 33/005
USPC 257/94; 438/38

(57) ABSTRACT

The subject invention relates to a light emitting device, including a first semiconductor layer having a first conductive type; a second semiconductor layer having a second conductive type, wherein the second conductive type is different from the first conductive type; and a passivation layer covering the first and the second semiconductor layers, wherein the passivation layer has a rough surface made from a roughing treatment. The subject invention further discloses a manufacturing method for such light emitting device. The structure of the light emitting device of the subject invention can eliminate unnecessary elements, reduce process time, facilitate control of light emitting shape and further improve light emitting efficiency.

### BACKGROUND OF THE INVENTION

1. Field of the Invention

The present invention relates to a light emitting device, and more particularly to a light emitting device of a tight-emitting diode.

2. Description of the Related Art

Generally, conventional light-emitting diode package (LED package) isolates light-emitting diode chip from external by encircling the light-emitting diode chip with a packaging material. Therefore, light emitted from the tight-emitting diode chip needs to be emitted in such a way that it passes through the packing material.

Prior art has disclosed a method for improving light emitting efficiency of light-emitting diode package to achieve needed light emitting efficiency by improving the structure of packaging body. For example, U.S. Pat. No. 8,089,083 discloses that after a light-emitting diode chip is formed, the light-emitting diode chip is surrounded with a packaging material, and by changing the structure of the packaging material, such as by adding a reflective layer or roughing the package material, refractive index can be adjusted.

However, in conventional packaging method, a packaging step performed after the formation of the light-emitting diode chip may change light emitting characteristics of the light-emitting diode chip; in other words, characteristics, such as a light emitting wavelength, light emitting intensity and tight emitting direction, may be effected by the chosen packaging materials.

Moreover, additional packaging material also causes that the heat generated from the light-emitting diode chip during operation cannot be dissipated well but instead to accumulate near the light-emitting diode chip, so that light emitting efficiency of the light-emitting diode chip is further reduced.

Therefore, in view of the defects found in prior art, the objective of the present invention is to provide a light emitting device which enables light emitting efficiency to be unaffected after the preparation of light-emitting diode chip without additional packaging step, so that the manufacturing cost and process time of light emitting device can be reduced, the light emitting shape can be easily controlled and the overall light emitting efficiency of the light emitting device can be further improved.

### SUMMARY OF THE INVENTION

The objective of the present invention is to eliminate problems caused by defects found in prior art and to produce a low-cost and high-capacity light emitting device with high light emitting efficiency. Compared with techniques currently seen in the market, the present invention is capable of minimizing unnecessary manufacturing cost, reducing processes and improving light emitting efficiency.

An embodiment of the present invention relates to a light emitting device, which includes a first semiconductor layer having a first conductive type; a second semiconductor layer having a second conductive type, where the second conductive type is different from the first conductive type; and a passivation layer covering the first and the second semiconductor layers, where the passivation layer has a rough surface achieved from a roughing treatment.

Another embodiment of the present invention provides a manufacturing method for a light emitting device, which includes: forming a first semiconductor layer having a first conductive type; forming a second semiconductor layer having a second conductive type, where the second conductive type is different from the first conductive type; forming a passivation layer covering the first and the second semiconductor layers; and roughing the passivation layer.

### BRIEF DESCRIPTION OF THE DRAWINGS

The invention is described according to the appended drawings where:

FIG. 1 shows a light emitting device of an embodiment of the present invention;

FIG. 2 shows a light emitting device of another embodiment of the present invention;

FIG. 3 shows a light emitting device of still another embodiment of the present invention; and

FIG. 4 shows a light emitting device of yet another embodiment of the present invention.

### PREFERRED EMBODIMENT OF THE PRESENT INVENTION

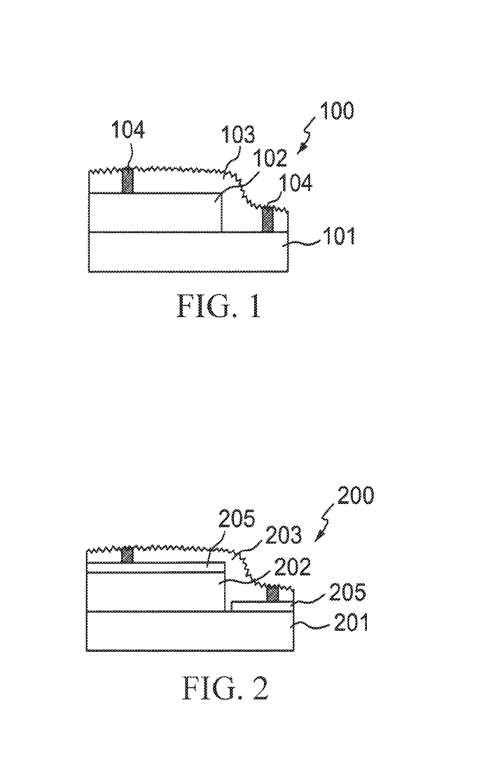

An embodiment of the present invention provides a manufacturing method for a light emitting device 100, as shown in FIG. 1, which includes: forming a first semiconductor layer 101 having a first conductive type; forming a second semiconductor layer 102 having a second conductive type, where the second conductive type is different from the first conductive type; forming a passivation layer 103 covering the first semiconductor layer 101 and the second semiconductor layer 102; and performing a roughing treatment on a surface of the passivation layer 103, so as to give the passivation layer 103 a rough surface.

In a preferred embodiment, the first conductive type and the second first conductive type are respectively an N-type semiconductor and a P-type semiconductor, or vice versa. The first conductive layer 101 and the second conductive layer 102 both constitute a light-emitting diode element. For example, the first semiconductor layer may be an N-type gallium nitride (n-GaN) layer and the second semiconductor layer may be a P-type gallium nitride (p-GaN) layer. A multiple quantum well (MQW) layer may be further formed between the first semiconductor layer 101 and the second semiconductor layer 102. Moreover, a conductive contact 104 may be further formed on the passivation layer 103 so as to enable the first semiconductor layer 101 and the second semiconductor layer 102 to be electrically connected to an external power supply.

The objective of forming the passivation layer 103 is to prevent the first semiconductor layer 101 and the second semiconductor layer 102 from being damaged by oxidation, which would affect light emitting efficiency. Furthermore, when light sent from the light-emitting diode element reaches the surface of the passivation layer 103, light irradiates the surface structure made from a roughing treatment, so that the probability for the incident angle of the light irradiating the surface of the passivation layer 103 to be larger than a total reflection critical angle can be increased, thereby improving light emitting efficiency.

In a preferred embodiment, the passivation layer 103 is essentially transparent; a refractive index thereof is about between 1.2 and 2.5 and the material thereof may be the essentially transparent material, such as silicon oxide, silicon nitride, spin-on glass (SOG), silica gel, epoxy resin (Epoxy), polymethyl methacrylate (PMMA) or high molecular polymer. The passivation layer 103 may be formed by means of spin on, evaporation or sputtering.

In a preferred embodiment, after the passivation layer 103 is formed, to form a pattern on the passivation layer 103, roughing treatment is performed on the surface, which includes: forming the pattern on the passivation layer 103 through a lithography process, and etching the passivation layer 103 so as to give the passivation layer 103 a patterned rough surface. The rough patterned surface may be formed with an optical crystal structure. Moreover, the pattern of the rough patterned surface may be designed according to light emitting demands, such as the demand to adjust a refractive index or a light emitting direction.

In the step of etching the passivation layer 103 to form the rough surface, etchant may be used to perform wet etching on the passivation layer 103, or plasma or ion may be used to perform dry etching.

In a preferred embodiment, the thickness of the passivation layer 103 is about between 10 nm to 100 μm, which may be determined according to light emitting demand. Generally, the thicker the passivation layer 103 is, the deeper the depth of etching is, so that surface roughing effect is significant and light emitting efficiency is improved.

After the passivation layer 103 made from the roughing treatment is formed, die cutting may be further performed. The cut die may be directly applied to lighting devices without any additional packaging step. Therefore, light emitting shapes and light emitting efficiency of light emitting devices finished according to the method provided in the present invention will not be affected by the additional packaging.

Furthermore, the passivation layer 103 may include a phosphor, such as cerium-doped yttrium aluminum garnet (Ce: YAG) or terbium aluminum garnet (YAG), so that the wavelength of light sent from the light-emitting diode element may be changed.

Another preferred embodiment of the present invention is shown in FIG. 2. A conductive layer 205 may be further formed between a passivation layer 203 and a first semiconductor layer 201 and/or between a passivation layer 203 and a second semiconductor layer 202, where the material of the conductive layer may be indium tin oxide (ITO), metal or conducting polymer.

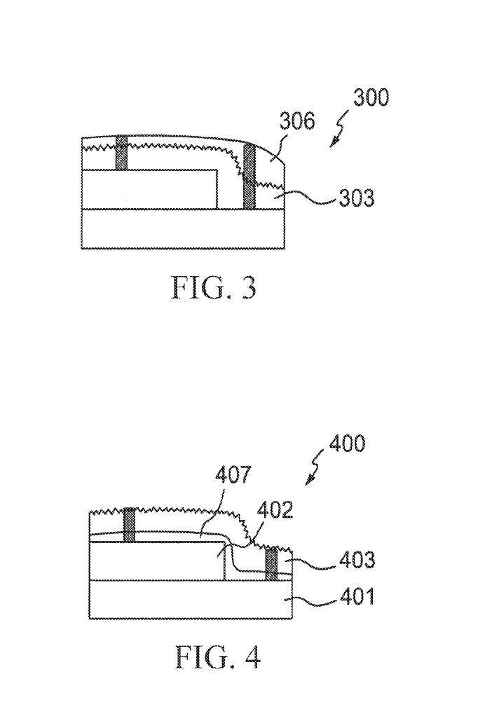

In still another preferred embodiment of the present invention, a light emitting device 300 shown in FIG. 3 is formed. After the roughing treatment is performed on a passivation layer 303, a conventional packaging layer 306 is further formed on the passivation layer 303. The packaging layer 306 may further include a fluorescent layer or fluorescent material uniformly distributed throughout the packaging layer 306 so as to change the color of light according to demands. Moreover, after the passivation layer 303 has been roughed and the packaging layer 306 has been formed, die cutting may be further performed. In another preferred embodiment, after the roughing step of the passivation layer 303 and the die cutting step have been completed, the packaging layer 306 may be formed to cover the cut die.

In yet another preferred embodiment of the present invention, a light emitting device 400 shown in FIG. 4 is formed. After a first semiconductor layer 401 and a second semiconductor layer 402 are formed, and before a passivation layer 403 is formed, an intermediate layer 407 is formed. The intermediate layer 407 covers the first semiconductor layer 401 and the second semiconductor layer 402, so that the intermediate layer 407 may be located between the latter formed passivation layer 403 and the light-emitting diode element of the first semiconductor layer 401 and the second semiconductor layer 402. The intermediate layer 407 may be used as an additional passivation layer to further protect the first semiconductor layer 401 and the second semiconductor layer 402 from being damaged during the procedure of roughing performed on the passivation layer 403. Furthermore, the intermediate layer 407 may be formed after a conductive layer is formed on the first semiconductor layer 401 and/or the second semiconductor layer 402. After the roughing treatment is performed on the passivation layer 403, die may be further cut.

In another preferred embodiment, die cutting may be preformed after the intermediate layer 407 is formed, and then the passivation layer 403 is formed to cover the cut die while roughing the passivation layer 403. After that, a packaging layer may be further formed to cover the roughed passivation layer 403.

Light emitting device made according to the method provided in the present invention has a roughed passivation layer, so that the objective of protecting the light-emitting diode element can be achieved without forming additional packaging material, thereby reducing processes, decreasing production cost and achieving the objective of improving light emitting efficiency.

The technical content and features of the present invention have been described above, but persons skilled in the art can make various variations and modifications to the disclosed technical content and features without departing from the teachings and disclosure of the present invention. Therefore, the scope of the present invention is not limited to the described embodiments, but also covers various variations and modifications made without departing from the present invention as defined by the appended claims.

What is claimed is:

1. A light emitting device, comprising:
a first semiconductor layer having a first conductive type;
a second semiconductor layer having a second conductive type, wherein the second conductive type is different from the first conductive type; and
a passivation layer covering the first and the second semiconductor layers, wherein the passivation layer has a rough surface made from a roughing treatment.

2. The light emitting device according to claim 1, wherein the passivation layer comprises an optical crystal structure.

3. The light emitting device according to claim 1, wherein the passivation layer is essentially transparent and a refractive index thereof is about between 1.2 and 2.5.

4. The light emitting device according to claim 3, wherein the passivation layer is made of silicon oxide, silicon nitride, spin-on glass (SOG), epoxy resin (Epoxy), polymethyl methacrylate (PMMA), silica gel or high molecular polymer.

5. The light emitting device according to claim 1, further comprising a conductive layer, arranged between the passivation layer and the first semiconductor layer or between the passivation layer and the second semiconductor layer.

6. The light emitting device according to claim 1, further comprising an intermediate layer between the passivation layer and the first and the second semiconductor layers.

7. The light emitting device according to claim 1, wherein the thickness of the passivation layer is about between 10 nm and 100 μm.

8. The light emitting device according to claim 1, further comprising a packaging layer covering the passivation layer.

9. A manufacturing method for a light emitting device, comprising:
forming a first semiconductor layer having a first conductive type;
forming a second semiconductor layer having a second conductive type, wherein the second conductive type is different from the first conductive type;
forming a passivation layer covering the first and the second semiconductor layers; and
roughing the passivation layer.

10. The method according to claim 9, wherein the step of roughing the passivation layer comprises: etching the passivation layer so as to form a rough surface.

11. The method according to claim 10, further comprising: patterning the passivation layer so as to enable the forming of an optical crystal structure of the passivation layer.

12. The method according to claim 9, further comprising: forming a conductive layer between the passivation layer and the first semiconductor layer or between the passivation layer and the second semiconductor layer.

13. The method according to claim 9, further comprising: forming an intermediate layer between the passivation layer and the first and the second semiconductor layers before the passivation layer is formed.

14. The method according to claim 9, further comprising: forming a packaging layer on the passivation layer.
